(19) United States
(12) Patent Application Publication
(10) Pub. No.: US 2004/0027063 A1
(43) Pub. Date: Feb. 12, 2004

(54) Organic EL panel and manufacturing method thereof

(76) Inventor: Ryuji Nishikawa, Gifu-shi (JP)

Correspondence Address: CANTOR COLBURN, LLP, 55 GRIFFIN ROAD SOUTH, BLOOMFIELD, CT, 06002

(21) Appl. No.: 10/386,818

(22) Filed: Mar. 12, 2003

(30) Foreign Application Priority Data
Mar. 13, 2002 (JP) 2002-68751

(51) Int. Cl. H01J 1/62

(52) U.S. Cl. 313/506

(57) ABSTRACT

A hole transport layer has a thickness of 170 nm or larger. This can prevent a hole transport layer from being broken down even when a cathode is partly in contact with the surface of the hole transport layer due to dust introduced during manufacturing of an organic emissive layer, and leads to suppression of defects.

### BACKGROUND OF THE INVENTION

1. Field of the Invention

The present invention relates to an organic EL panel in which organic EL elements are arranged in a matrix, each organic EL element having at least an organic emissive layer and a hole transport layer intervening between a pair of electrodes.

2. Description of the Related Art

A conventionally known flat display panel is an organic EL display panel. Organic EL display panels are self-emissive, which is different from liquid crystal display panels (LCD), and are very much expected to come into wide use as bright and easy-to-view flat display panels.

An organic EL display includes, as pixels, a number of organic EL elements arranged in a matrix. An organic EL element has a structure in which a hole transport layer, an organic emissive layer, and a cathode made of aluminum or the like are stacked on an anode made of ITO or the like. An electron transport layer may often be provided between the organic emissive layer and the cathode.

Here, an anode and an organic emissive layer are patterned so as to be present only in an emissive region for every pixel. That is, anodes are formed in a discrete manner in order to supply current for every pixel, and separate organic emissive layers are necessary for different colors. Such separate formation of organic emissive layers is also useful in order to clearly distinguish the pixels by avoiding light emission from a part between adjacent pixels.

Meanwhile, a hole transport layer and a cathode are formed over the entire surface of all of the pixels without using a mask, taking advantage of ease of processing without using a mask. Note that a cathode also serves to separate the concerned organic EL element from the space above.

Display is carried out using the thus formed organic EL panel.

In testing a finish organic EL element, some pixels may be found to be defective if failing to perform desired emission. The defect may be due to a problem with a thin film transistor (TFT) for controlling current supply, or with the organic EL element itself.

Defective pixels include bright spot defective pixels which continuously emit light and dark spots which do not emit light, and problematic organics EL element generally result in the latter.

Examination of such defective organic EL elements has led to the discovery that introduction of dusts into an organic emissive layer during manufacturing may cause the defect. That is, where an emissive layer must be formed in an individual pattern for every pixel (an electron transport layer may often be formed in the same pattern as that of an organic emissive layer), as described above, and the pattern formation is achieved by means of evaporation using a mask disposed in front of an evaporation source, the use of a mask brings dust into the evaporation environment, resulting in an organic emission layer with dust introduced therein.

Such dust introduced during fabrication of an organic emissive layer and then resting on the hole transport layer cannot be fully covered by a thin organic emissive layer (and an electron transport layer). As a result, the cathode is brought into direct contact with the hole transport layer around the dust and resultantly opposed to the anode via the hold transport layer while leaving only a narrow space between the cathode and the anode. This causes leakage current at that point and eventually forms a pixel which does not emit light.

### SUMMARY OF THE INVENTION

The present invention relates to manufacturing of an organic EL panel, which can effectively prevent dark spots.

According to the present invention, a hole transport layer has a thickness of more than 150 nm, preferably 170 nm or more. A hole transport layer having that thickness can reliably prevent breakdown even when dust is introduced into an organic emissive layer and a cathode is resultantly brought into contact with the upper surface of the hole transport layer. This arrangement enables a reduction in the occurrence of defective organic EL elements.

### BRIEF DESCRIPTION OF THE DRAWINGS

FIG. 1 is a diagram showing a structure of a pixel;

FIG. 2 is a diagram showing a structure of respective layers with dust introduced therein;

FIG. 3 shows a structure of respective layers including a thick hole transport layer with dust introduced therein;

FIG. 4 is a diagram showing a structure with a pattern deposited in a displaced position; and

FIG. 5 is a diagram showing characteristics of leakage current.

### DESCRIPTION OF THE PREFERRED EMBODIMENTS

In the following, an embodiment of the present invention will be described with reference to the accompanied drawings.

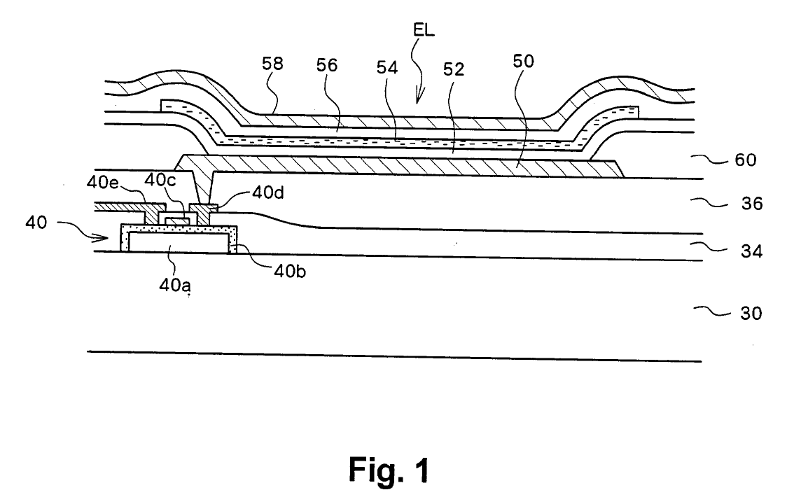

FIG. 1 shows a structure of a pixel. The drawing illustrates only a driving TFT 40 and an organic EL element, whereas two TFTs, one capacitor, and one organic EL element are in fact formed for every pixel on an active matrix element substrate.

The shown element substrate comprises a driving TFT 40 formed on a glass substrate 30. The structure of the driving TFT 40 and the glass substrate 30 is shown in FIG. 1. The driving TFT 40, formed on the glass substrate 30, includes an active layer 40a made of low temperature poly-silicon. Both ends of the active layer 40a are doped with impurities and constitute source and drain regions, respectively, and the center thereof constitutes a channel region. Lying above the channel region via a gate insulating film 40b made of silicon oxide is a gate electrode 40c. The gate insulating film 40b and the gate electrode 40c are covered by an inter-layer insulating film 34. On both sides of the gate electrode 40c are formed a source electrode 40d and a drain electrode 40e, respectively, which are connected through a contact hole formed throughout the inter-layer insulating film 34 to the source and drain regions, respectively. The top ends of the source electrode 32d and the drain electrode 32e are located on the surface of the inter-layered insulating film 34.

Lying on the surface of the inter-layered insulating film 34 is a metallic wire or the like which connects the drain electrode 40e and the power source line VL. Further, a first planarization film 36 is formed covering the inter-layer insulating film 34.

On the top surface of the first planarization film 36, a transparent electrode 50 made of ITO is formed with one end thereof being connected to the source electrode 40d of the driving TFT 40 through a contact hole formed throughout the first planarization film 36.

The transparent electrode 50 constitutes an anode of the organic EL element. A hole transport layer 52, an organic emissive layer 54, an electron transport layer 56, and a metal cathode 58 are formed on the transparent electrode 50, and a second planarization film 60 is formed around and an outer area of the transparent electrode 50. The organic emissive layer 54, which is larger than the transparent electrode 50 to cover the transparent electrode 50 even if the organic emission layer is displaced slightly, extends to above the second planarization film 60 and terminates at a position so as to remain only within a pixel region. Meanwhile, the hole transport layer 52 and the electron transport layer 56 are formed covering the entire surface of all of the pixels. It should be noted that the electron transport layer 56, which may contain light emissive material such as Alq₃, may often be formed so as to remain only within an emission region, similar to the organic emissive layer 54.

In the above described structure, the organic emissive layer 54 is formed by means of patterning for every pixel. The patterning is achieved by defining, using a mask, evaporated materials in vacuum evaporation. The mask is likely to attract dust and, in particular, it is almost impossible to prevent the attachment of dust particles of about 0.3 μm or smaller to the mask.

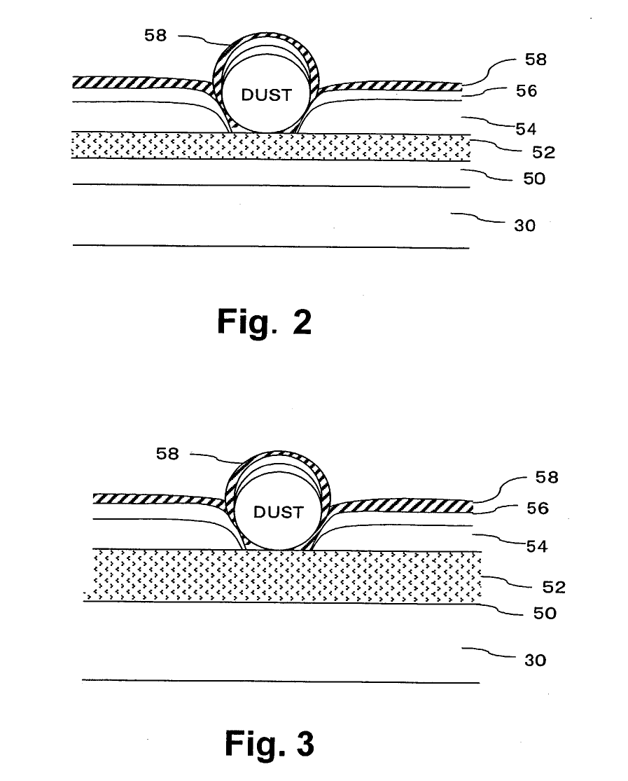

Introduction of such dust during formation of an organic emissive layer 54 results in separation of the organic emissive layer 54, as shown in FIG. 2, which causes a discontinuous part around the dust during subsequent formation of the electron transport layer 56 and the cathode 58. As a result, the cathode is partially brought into direct contact with the hole transport layer 52.

With such an organic EL element, in application of the maximum voltage, the applied voltage, for example 12V, is directed to the hole transport layer 52, which in turn is thereby broken down and causes shorts. Consequently, a defective pixel results. Once such alteration occurs, the alteration may spread across the surface of the hole transport layer 52, which makes the surrounding pixels vulnerable to the alteration.

In this embodiment, because the hole transport layer 52 is formed having a thickness of more than 150 nm, preferably, 170 nm or more, as shown in FIG. 3, even a voltage of as much as 12 V does not cause breakdown with the hole transport layer 52. That is, should dust be introduced, the hole transport layer 52 is saved from being broken down and the above described defect can thus be avoided.

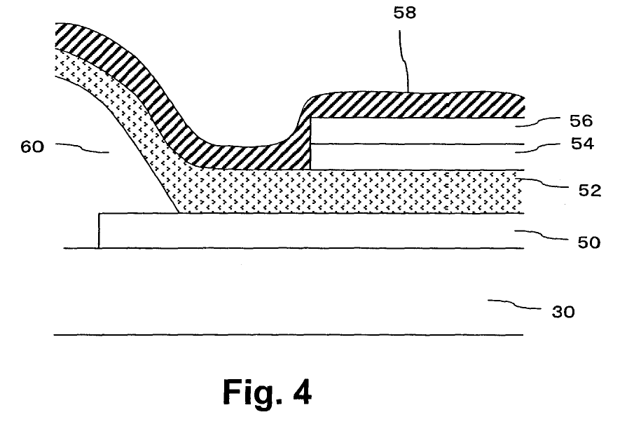

Moreover, in the case where the organic emissive layer 54 is formed in a displaced position, no organic emissive layer 54 may be present above the transparent electrode 50, as shown in FIG. 4, and therefore, a large voltage is applied to the hole transport layer 52. In this embodiment, however, breakdown can be avoided due to the hole transport layer 52 having a relatively large thickness. Note that the shown electron transport layer 56 is patterned corresponding to each pixel, similar to the organic emissive layer 54.

Further, in any of the cases where no electron transport layer 56 is formedor the electron transport layer 56 is patterned using a mask, the same as the organic emissive layer 54, the transparent electrode 50 and the cathode 58 are likely to be opposed to each other via the hole transport layer 52. In such a case, the applied voltage is directed to both ends of the hole transport layer 52.

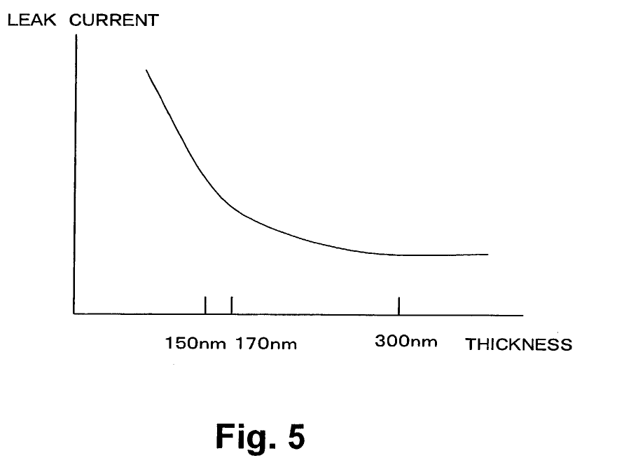

In view of the above, in this embodiment, the hole transport layer 52 is made of NPD (dimmer of triphenylamine) or NPB (N,N-di (naphthalene-1-yl)-N,N-diphenyl-benzidene). FIG. 5 shows correlation between between leakage current and the thickness of the hole transport layer 52 made of NPDIt will be appreciated from the graph that the hole transport layer 52 having a thickness of more than 150 nm, preferably 170 nm or more can reduce current leakage from a portion between the anode and the cathode of an organic EL element, so that breakdown can be avoided.

It should be noted, in view of prevention of leakage current, that a thicker hole transport layer 52 is more preferable. However, in view of function of an organic EL element, a thinner hole transport layer 52 is preferred. In addition, it is also known from FIG. 5 that a thickness of 300 nm or larger does not significantly increase the leakage current prevention effect. Moreover, a thicker hole transport layer 52 results in another drawback of increased cost.

In addition, the thickness of the hole transport layer 52 affects interference of transmitting light. That is, for light in a blue region with a relatively small wavelength, better transmission efficiency can be achieved with a hole transport layer 52 having a thickness of about 240 nm. Therefore, a thickness in a range of 240 nm+20% can provide relatively better transmission efficiency. Also in view of this, the thickness of a hole transport layer 52 is preferably 300 nm or smaller.

Here, an organic EL panel has two types, namely RGB type in which different emissive materials are used for every pixel so that each pixel emits light of either one of RGB colors, and another type in which all pixels emits light of the same color, for example, white, which is then changed to any of RGB colors using a color filter or the like.

It has been found that, for the RGB type, a hole transport layer 52 having a thickness of 180 nm to 190 nm is most appropriate for use with a panel in consideration of emission efficiency of the respective colors. For the type with white emissive color, in which orange and blue emissive layers are preferably stacked so that the combined light from both layers results in white, the thickness of a hole transport layer 52 is preferably in a range of 240 nm+20%.

What is claimed is:

1. An organic EL panel in which organic EL elements are arranged in a matrix, each organic EL element having at least an organic emissive layer and a hole transport layer intervening between a pair of electrodes,
wherein
the hole transport layer has a thickness of more than 150 nm, preferably 170 nm or more.

2. The organic EL panel according to claim 1, wherein the hole transport layer contains, as a hole transport material, NPD or NPB.

3. The organic EL panel according to claim 1, wherein, at a part around the organic EL element, the pair of electrodes are opposed to each other via the hole transport layer.

4. The organic EL panel according to claim 1, wherein the hole transport layer has a thickness of 300 nm or smaller.

5. A method for manufacturing an organic EL panel in which organic EL elements are arranged in a matrix, each organic EL element having at least an organic emissive layer and a hole transport layer intervening between a pair of electrodes, comprising the steps of:
forming an anode of the organic EL element;
forming a hole transport layer having a thickness of 170 nm or more so as to cover an entire surface of the organic elements arranged in a matrix; and forming an organic emissive layer, using a mask, for every organic EL element segmented in the hole transport layer.

6. The method according to claim 5, wherein the hole transport layer contains, as a hole transport material, NPD or NPB.

7. The method according to claim 5, wherein the hole transport layer has a thickness of 300 nm or smaller.
